(19) United States
(12) Patent Application Publication
(10) Pub. No.: US 2025/0116688 A1
(43) Pub. Date: Apr. 10, 2025

(54) DEVICES AND METHODS FOR DETERMINING AN ELECTRICAL OVERCURRENT EVENT

(71) Applicant: Infineon Technologies AG, Neubiberg (DE)

(72) Inventors: Thomas HAFNER, Magdalensberg (AT); Giampiero CIAMMETTI, Villach (AT)

(21) Appl. No.: 18/904,140

(22) Filed: Oct. 2, 2024

(30) Foreign Application Priority Data
Oct. 4, 2023 (DE) 102023126912.7

(51) Int. Cl. G01R 19/165; H02H 3/087

(52) U.S. Cl. CPC G01R 19/16504; H02H 3/087

(57) ABSTRACT

A device for detecting an electrical overcurrent event includes a current sensor configured to generate a first sense signal representative of an absolute current value of an electrical current through an electrical conductor. The device further includes a sense unit configured to generate a second sense signal representative of a temporal change of the electrical current. The device further includes an adjustment unit configured to adjust a previously set first threshold value for the absolute current value based on the second sense signal. The device further includes a detection unit configured to detect an overcurrent event in the electrical conductor based on a comparison between the first sense signal and the adjusted first threshold value.

### CROSS-REFERENCE TO RELATED APPLICATION

This application claims priority to Germany Patent Application No. 102023126912.7 filed on Oct. 4, 2023, the content of which is incorporated by reference herein in its entirety.

### TECHNICAL FIELD

The present disclosure relates to devices for determining electrical overcurrent events. In addition, the present disclosure relates to methods for determining electrical overcurrent events that may be performed by such devices.

### BACKGROUND

Conventional electrical overcurrent detection may be based on sensing an electrical current and comparing the sensing result to a predetermined threshold value representing a maximum current that may flow before the current flow is interrupted. A drawback of such approach is that it may take a certain amount of time before the threshold value is reached, during which time the power and energy increases as well. In addition, even more time may pass due to a delay of the detection mechanism itself. Until a final switch-off event may occur, the rising electrical current may damage or even destroy the electrical system. Manufacturers and designers of devices for determining electrical overcurrent events are constantly striving to improve their products. In particular, it may be desirable to develop devices and methods providing a quick and reliable detection of electrical overcurrent events such that damage or destruction of the electrical system may be avoided.

### SUMMARY

An aspect of the present disclosure relates to a device for detecting an electrical overcurrent event. The device includes a current sensor configured to generate a first sense signal representative of an absolute current value of an electrical current through an electrical conductor. The device further includes a sense unit configured to generate a second sense signal representative of a temporal change of the electrical current. The device further includes an adjustment unit configured to adjust a previously set first threshold value for the absolute current value based on the second sense signal. The device further includes a detection unit configured to detect an overcurrent event in the electrical conductor based on a comparison between the first sense signal and the adjusted first threshold value.

A further aspect of the present disclosure relates to a method for detecting an electrical overcurrent event. The method includes an act of generating a first sense signal representative of an absolute current value of an electrical current through an electrical conductor. The method further includes an act of generating a second sense signal representative of a temporal change of the electrical current. The method further includes an act of setting a first threshold value for the absolute current value. The method further includes an act of adjusting the first threshold value based on the second sense signal. The method further includes an act of detecting an electrical overcurrent event in the electrical conductor based on a comparison between the first sense signal and the adjusted first threshold value.

### BRIEF DESCRIPTION OF THE DRAWINGS

Devices and methods in accordance with the disclosure are described in more detail below based on the drawings. Similar reference numerals may designate corresponding similar parts. The technical features of the various illustrated examples may be combined, provided they are not mutually exclusive, and/or may be selectively omitted if not described as being necessarily required.

FIG. 1 illustrates a block diagram of a device 100 for determining an electrical overcurrent event in accordance with the disclosure.

FIG. 2 illustrates a circuit diagram of a device 200 for determining an electrical overcurrent event in accordance with the disclosure.

FIG. 3 illustrates an electrical system 300s including a device 300 for determining an electrical overcurrent event in accordance with the disclosure.

FIG. 4 illustrates a flowchart of a method for determining an electrical overcurrent event in accordance with the disclosure.

FIG. 5 illustrates a timing diagram for detecting an electrical overcurrent event.

FIG. 6 illustrates a timing diagram for detecting an electrical overcurrent event using a device in accordance with the disclosure.

### DETAILED DESCRIPTION

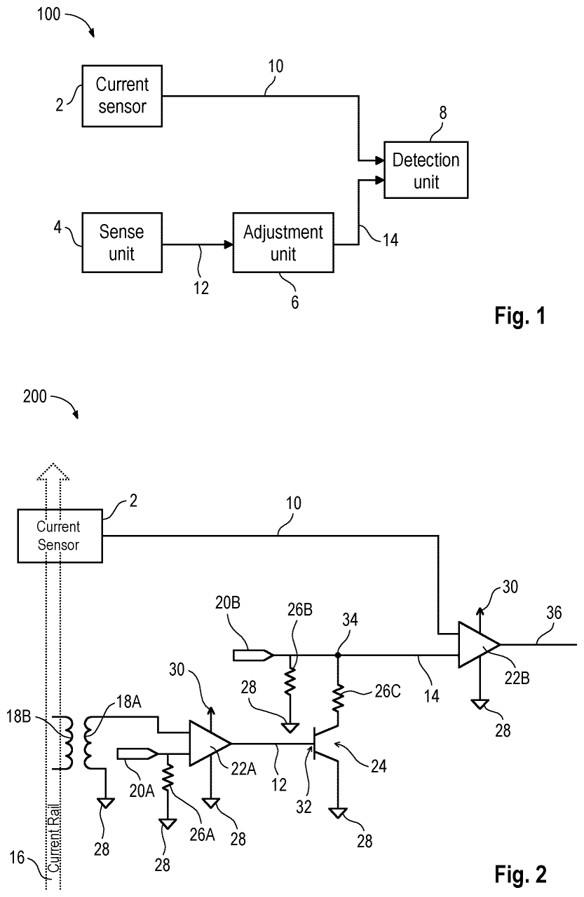

The device 100 of FIG. 1 is illustrated in a general manner in order to qualitatively specify aspects of the present disclosure. The device 100 may be extended by one or more aspects described in connection with other examples. For example, FIG. 2 described later on illustrates a more detailed version of a device 200 in accordance with the disclosure.

The device 100 may include a current sensor 2, a sense unit 4, an adjustment unit 6 and a detection unit 8. The current sensor 2 may be configured to generate a first sense signal 10 representative of an absolute current value of an electrical current through an electrical conductor (not shown). The sense unit 4 may be configured to generate a second sense signal 12 representative of a temporal change of the electrical current through the electrical conductor. The adjustment unit 6 may be configured to adjust a previously set first threshold value for the absolute current value based on the second sense signal 12. The detection unit 8 may be configured to detect an overcurrent event in the electrical conductor based on a comparison between the first sense signal 10 and the adjusted first threshold value 14. In particular, at least one of the sense unit 4, the adjustment unit 6, or the detection unit 8 may be implemented as a discrete component external to the current sensor 2. It is to be noted that an implementation of the components of the device 100 is not restricted to a specific type. Rather, the components of the device 100 may be implemented in various ways. More detailed example implementations of the device components are shown and described in connection with FIG. 2.

The device 200 of FIG. 2 may be regarded as a more detailed version of the device 100 of FIG. 1. The device 200 may be configured to detect an electrical overcurrent event that may occur in an electrical conductor 16 which may be seen as a part of the device 200 or not. In the illustrated example, the electrical conductor 16 may correspond to a current rail or a bus. The device 200 may include a current sensor 2, a first inductor 18A, a first IDAC (Current Digital to Analog Converter) 20A, a second IDAC 20B, a first comparator 22A, a second comparator 22B, a transistor 24 as well as multiple resistors 26A, 26B, and 26C that may be connected as illustrated in FIG. 2.

The current sensor 2 may be configured to generate and output a first sense signal 10 representative of an absolute current value of an electrical current flowing through the electrical conductor 16. In particular, the first sense signal 10 may be an analog signal. The current sensor 2 is not restricted to a specific type, and sensing the electrical current may be based on any suitable technique. For example, the current sensor 2 may be Hall based, magnetoresistance (MR) based, shunt resistor based, a current transformer (for AC only), etc. The current sensor 2 may output the first sense signal 10 to a first (upper) input of the second comparator 22B.

A second inductor 18B may be connected in a path of the electrical current through the electrical conductor 16. The second inductor 18B may be seen as a part of the device 200 or not. The first inductor 18A may be coupled to the second inductor 18B, e.g., the inductors 18A and 18B may be coupled inductors. For the case of medium voltage (MV) and high voltage (HV) electrical systems (such as e.g., an 800V DC system), a galvanic isolation between the first inductor 18A and the electrical conductor 16 may be provided in order to satisfy specific clearance and creepage requirements.

A temporal change (or slope) of the electrical current through the electrical conductor 16 may result in a voltage induced across the first inductor 18A. In particular, the induced voltage U may be based on the formula

$$U ( t ) = L \cdot \frac{dI ( t )}{dt} ,$$

wherein U is the induced/measured voltage across the inductance L of the first inductor 18A, and dl(t)/dt is the temporal change (or slope) of the electrical current I through the electrical conductor 16.

Detecting the temporal change of the electrical current I may be performed making use of the principle of self-inductance. In this regard, it is to be noted that the inductance value L of the first inductor 18A may be well-defined and precisely known. That is, the induced voltage U and thus the temporal change of the electrical current through the electrical conductor 16 may be determined in a precise and reliable way. In a non-limiting example, a temporal change of about 800 A/μs and an inductance L of about 10 nH may result in a voltage across the first inductor 18A of about 8 V. Accordingly, since a small inductance L of about 10 nH may obviously provide a sufficiently strong induced voltage of about 8 V, the first inductor 18A does not necessarily add too much of an unwanted inductance to the device 200 or an electrical system including the device 200. A sense signal representative of the temporal change of the electrical current may be provided to a first (upper) input of the first comparator 22A.

The first inductor 18A may be implemented in various different ways. The following examples for implementing the first inductance 18A may have in common that no additional inductance may need to be introduced, but an already available inductance of a respective implementation may be used. In particular, a value of an already available inductance may be well-defined and precisely known.

In one example, the first inductor 18A may be a coil structure that may be integrated into the current sensor 2. In this connection, it may be possible to e.g., integrate a dedicated sensing coil structure into a current sensing ASIC. In a further example, the first inductor 18A may be a wire-on-chip structure configured for a calibration of the current sensor 2. That is, the wire-on-chip usually used for a calibration may be used as sensing element. In another example, the first inductor 18A may be implemented as a PCB coil structure, wherein the current rail 16 may be used as primary inductance. In a further example, the first inductor 18A may be integrated into a power device, such as e.g., a wide bandgap switch. In yet another example, the first inductor 18A may be implemented in form of a dedicated coupled inductor as a secondary winding of a current slope limiting inductor (if used) or any other inductor that may be present in the considered application.

The first IDAC 20A may be configured to provide a signal representative of a second threshold value for the voltage induced across the first inductor 18A. In particular, the signal provided by the first IDAC 20A may be an analog signal. In this regard, it is to be noted that providing the second threshold value (or a corresponding threshold voltage) is not limited to the usage of the first IDAC 20A. Rather, providing the second threshold value may also be based on other suitable components or techniques, such as e.g., a voltage/resistor divider, (filtered) Pulse Width Modulation (PWM), VDAC (Voltage Digital to Analog Converter), etc. The second threshold value may be variably set and may be static during an operation of the device 200. Since the induced voltage across the first inductor 18A may be associated with a temporal change of the current through the electrical conductor 16, the second threshold value may be referred to as current slope threshold value. An output of the first IDAC 20A may be provided to a second (lower) input of the first comparator 22A.

The first comparator 22A may be supplied by a supply voltage (see signal ground 28 and pin 30 for the supply voltage). The first comparator 22A may be configured to receive the previously described signals from the first inductor 18A and the first IDAC 20A and may perform a comparison between the voltage induced across the first inductor 18A and the set second threshold value. Based on such comparison the first comparator 18A may be configured to output a second sense signal 12. In particular, the second sense signal 12 may correspond to a voltage that is proportional to the temporal change (or slope) of the electrical current through the electrical conductor 16. Referring back to the example of FIG. 1, the sense unit 4 of FIG. 1 may include at least one of the first inductor 18A, the first IDAC 20A, and/or the first comparator 22A of FIG. 2.

The second IDAC 20B may be configured to provide a signal representative of the first threshold value for the absolute current value of the electrical current through the electrical conductor 16. In particular, the signal provided by the second IDAC 20B may be an analog signal. In this regard, it is to be noted that providing the first threshold value (or a corresponding threshold voltage) is not limited to the usage of the second IDAC 20B. Rather, providing the first threshold value may also be based on other suitable components or techniques, such as e.g., a voltage/resistor divider, (filtered) Pulse Width Modulation (PWM), VDAC (Voltage Digital to Analog Converter), etc. The first threshold value may be variably set and may be static during an operation of the device 200. The first threshold value may be referred to as absolute current threshold value. The output signal of the second IDAC 20B may be adjusted (in particular lowered) based on an output of the transistor 24 as described in the following.

The transistor 24 is not restricted to a specific type. In one example, the transistor 24 may be a field effect transistor including a gate terminal, a drain terminal and a source terminal. In a further example, the transistor 24 may be a bipolar junction transistor including a base terminal, a collector terminal and an emitter terminal. A control terminal 32 (e.g., gate or base) of the transistor 24 may be connected to an output of the first comparator 22A. In addition, the lower terminal of the transistor 24 may be connected to signal ground 28 while the upper terminal of the transistor 24 may be coupled to a node 34 arranged between the output of the second IDAC 20B and a second (lower) input of the second comparator 22B.

The transistor 24 may be configured to adjust (in particular lower) the first threshold value for the absolute current value as output by the second IDAC 20B. In this regard, an input of the control terminal 32 of the transistor 24 may be based on the second sense signal 12 provided by the first comparator 22A. That is, an amount by which the first threshold value is lowered may be based on the second sense signal 12 and thus based on the temporal change of the electrical current through the electrical conductor 16. Referring back to the example of FIG. 1, the adjustment unit 6 of FIG. 1 may include the transistor 24 of FIG. 2. In this connection, it is to be noted that in a further example, the first comparator 22A may be replaced by an amplifier configured to linearly drive the input of the transistor 24. In such case, the transistor 24 may not only be driven on/off as with the output of the first comparator 22A, moreover it may be controlled linearly depending on the amount of voltage, respectively rate of change of current, given by the inductor 18A. The greater a temporal increase of the electrical current through the electrical conductor 16, the more the first threshold value may be lowered, in particular if a linear amplifier is used.

The second (lower) input of the second comparator 22B may be configured to receive the adjusted first threshold value 14 in form of an analog signal. In addition, as previously described, the first sense signal 10 may be received at the first (upper) input of the second comparator 22B. The second comparator 22B may be configured to compare the first sense signal 10 and the adjusted first threshold value 14 and to provide an output signal based on this comparison. The output signal 36 may represent a detection signal configured to indicate an electrical overcurrent event in the electrical conductor 16. If the measured absolute current value is greater than the adjusted first threshold value, an electrical overcurrent event may have occurred and may thus be indicated by the detection signal 36. Referring back to the example of FIG. 1, the detection unit 8 of FIG. 1 may include the second comparator 22B.

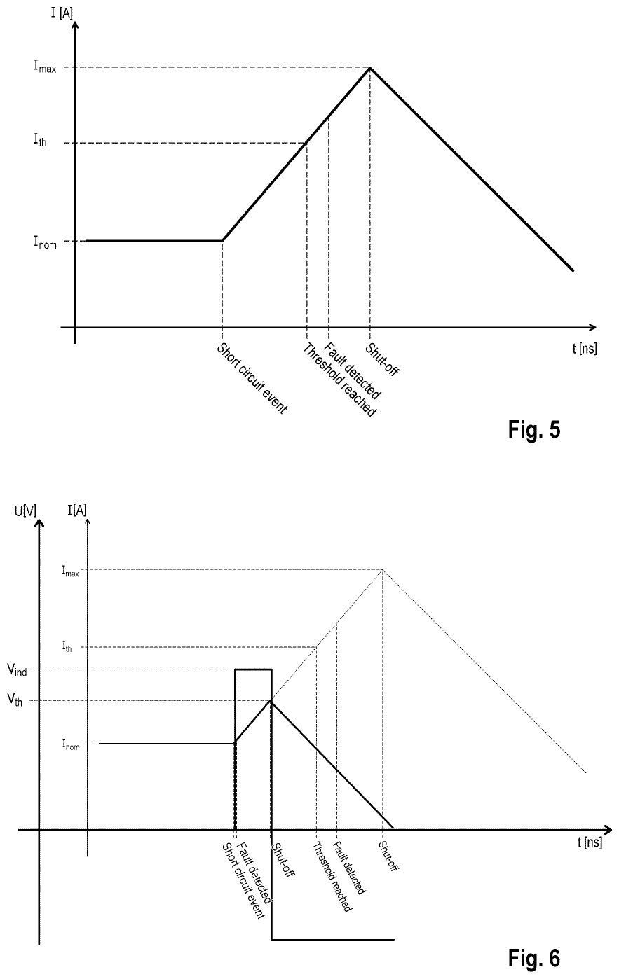

The device 200 in accordance with the disclosure may outperform conventional devices with regard to a detection of an electrical overcurrent event in the electrical conductor 16. In order to detect such electrical overcurrent event, conventional devices may only perform a simple comparison between the measured absolute current value of the electrical current and a (not adjusted) first threshold value. However, such approach may be flawed, because a certain time interval may pass until the overcurrent event is detected and the electrical current through the electrical conductor 16 can be switched off. During this delay the electrical current may still rise and may even become so high that it may damage or destroy the device. An example timing diagram for detecting an electrical overcurrent event based on such conventional approach is shown and described in connection with FIG. 5.

In contrast to the described conventional approach, devices in accordance with the disclosure may not only take into account the measured absolute current value of the electrical current, but may additionally consider its time evolution or temporal change, e.g., dl(t)/dt. The temporal change of the electrical current includes information about the specific amount by which the electrical current increases over time. One possibility to account for this information is to add this specific amount of increase to the measured absolute current value such that a so adjusted absolute current value may exceed the first threshold value at an earlier time. An alternative approach providing the same effect is to lower the first threshold value by the specific amount as previously described in connection with FIG. 2. The first threshold value is reduced so that the electrical overcurrent event may be detected at an earlier time. In particular, the first threshold value may be reduced proportional to the temporal increase of the electrical current. The higher the temporal increase of the electrical current (e.g., the stronger the electrical current grows), the more the first threshold value is reduced. An example timing diagram for detecting an overcurrent event using a device in accordance with the disclosure is shown and described in connection with FIG. 6.

Short circuit events may result in a rapid increase of the electrical current. In one case, a temporal increase of the electrical current may have an example value of about 800 A/μs. Accordingly, it should be possible to respond to a short circuit event by interrupting the electrical current through the electrical conductor 16 within a timeframe of nanoseconds. In order to provide such quick reaction times, signal processing performed by devices in accordance with the disclosure may preferably be analog due to the very fast signal dynamics.

The device 200 may optionally be configured to activate and deactivate the discussed feature of additionally taking into account the temporal change dl(t)/dt when detecting the electrical overcurrent. The temporal change in a short circuit condition may be much higher than a temporal change of a nominal electrical current including a ripple. It may thus be possible to set a third threshold value for the temporal change. If the determined value of the temporal change is higher than the third threshold value, the temporal change may be taken into account when detecting electrical overcurrent events, otherwise not.

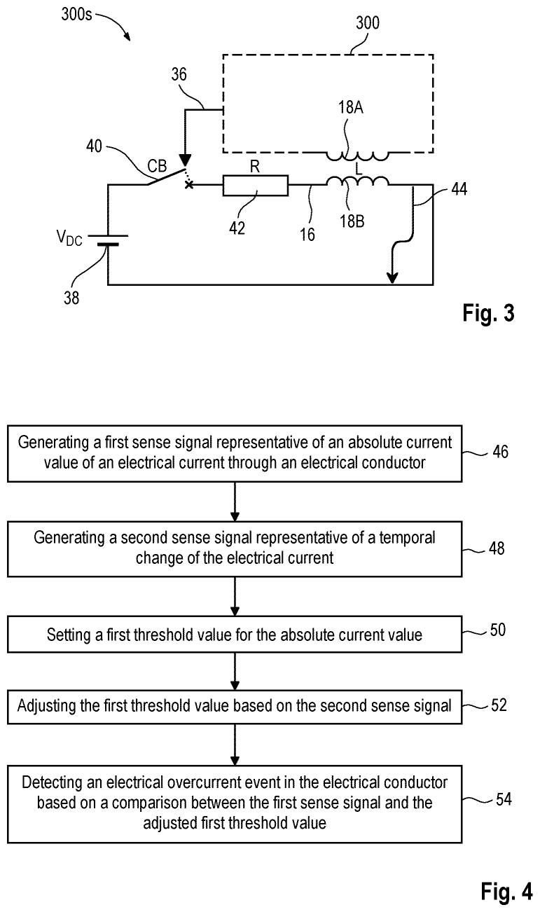

FIG. 3 illustrates an electrical system 300s including a device 300 for determining an electrical overcurrent event in accordance with the disclosure. The electrical system 300s may include or may correspond to a circuit including a DC power supply 38, a circuit breaker 40, a resistor (or a load) 42, a second inductor 18B and the device 300. The circuit breaker 40 and the second inductor 18B may be seen as a part of the device 300 or not. For example, the circuit breaker 40 may be a solid-state circuit breaker. The device 300 may include some or all features of the devices 100 and 200 of FIGS. 1 and 2. For the sake of simplicity, the device 300 is illustrated as a simple rectangle, wherein only the first inductor 18A is explicitly shown in order to illustrate an inductive coupling between the first inductor 18A of the device 300 and the second inductor 18B of the circuit.

During a regular operation of the electrical system 300s the circuit breaker 40 may be closed and an electrical current may flow through the circuit and an electrical conductor 16 thereof. In some instances, a short circuit event 44 may occur which may result in an increase of the electrical current through the electrical conductor 16 within a very short time period. The device 300 may be configured to detect an associated electrical overcurrent event as described in connection with FIGS. 1 and 2. In this regard, the device 300 may output a detection signal 36 indicating the electrical overcurrent event. The circuit breaker 40 may be configured to receive the output signal 36 and to interrupt (or switch off) the electrical current in response to receiving the output signal 36 as a detection signal configured to indicate an electrical overcurrent event. In the illustrated example, the circuit breaker 40 is in an open state and the electrical current has been interrupted due to the short circuit event 44.

For example, the devices described herein may be used in various industrial and automotive applications. In some non-limiting examples, the described mechanisms may be integrated into current sensors, dedicated ASICs or power semiconductor components. In the non-limiting example of FIG. 3, the electrical system 300s may correspond to a direct current (DC) system (see DC power supply 38). DC distribution systems may be used in many residential and industrial applications, such as e.g., data centers, commercial and residential buildings, telecommunication systems, transport power networks, etc. Compared to AC systems, DC systems may provide higher power efficiency, less complexity and greater readiness for integration with various local power sources and electronic DC loads. However, it is to be understood that the concepts discussed herein are not necessarily restricted to DC electrical systems. In further examples, devices in accordance with the disclosure may also be used in AC electrical systems. Moreover, in the example of FIG. 3, one or more components of the system (such as e.g., an included current sensor) may generate an AC ripple that may be superimposed on the DC current.

FIG. 4 illustrates a flowchart of a method for detecting an electrical overcurrent event in accordance with the disclosure. The method may be performed by any of the previously described devices and may thus be read in connection with preceding figures. At 46, a first sense signal may be generated, wherein the first sense signal may be representative of an absolute current value of an electrical current through an electrical conductor. Referring back to the example of FIG. 2, the electrical current may flow through the current rail 16, and the current sensor 2 may generate the first sense signal 10 which is provided to the first (upper) input of the second comparator 22B.

At 48, a second sense signal may be generated, wherein the second sense signal may be representative of a temporal change of the electrical current. Referring back to the example of FIG. 2, the electrical current flowing through the current rail 16 may change over time such that an inductive coupling between the inductors 18A and 18B may result in an induced voltage across the first inductor 18A. The induced voltage may be measured, and the measurement signal may be provided to the first (upper) input of the first comparator 22A. In addition, a second threshold value for the induced voltage may be set and the first IDAC 20A (or an equivalent component as described above) may output a signal representative of the second threshold value to the second (lower) input of the first comparator 22A. A comparison between the induced voltage and the second threshold value may be performed by the first comparator 22A. Based on this comparison the first comparator 22A (or an equivalent component as described above) may output the second sense signal 12 representative of a temporal change of the electrical current. In particular, the second sense signal 12 may correspond to a voltage proportional to the temporal change of the electrical current through the current rail 16.

At 50, a first threshold value for the absolute current value may be set. Referring back to the example of FIG. 2, the second IDAC 20B (or an equivalent component as described above) may generate and output a signal representative of the first threshold value.

At 52, the first threshold value may be adjusted based on the second sense signal. Referring back to the example of FIG. 2, the second sense signal 12 (e.g., a voltage proportional to the temporal change of the electrical current) may be used as an input for the control terminal 32 of the transistor 24. The voltage applied to the control terminal 32 may control a current between the other terminals (e.g., source and drain) of the transistor 24. In particular, a current flowing between the other terminals of the transistor 24 may lower the signal that is output by the second IDAC 20B. The greater the voltage applied to the control terminal 32, the more the signal that is output by the second IDAC 20B may be lowered. Stated differently, the greater the increase of the electrical current through the current tail 16, the more the first threshold may be lowered.

At 54, an electrical overcurrent event in the electrical conductor may be detected based on a comparison between the first sense signal and the adjusted first threshold value. Referring back to the example of FIG. 2, the adjusted first threshold value 14 may be provided to the second (lower) input of the second comparator 22B. The second comparator 22B may perform a comparison between the adjusted first threshold value 14 and the first sense signal 10 received at the first (upper) input of the second comparator 22B. Based on the comparison the second comparator 22B may output the detection signal 36 indicating whether an electrical overcurrent event has occurred or not.

The method of FIG. 4 may include further acts. For example, the method may include a further act of interrupting the electrical current in response to detecting the electrical overcurrent event. Referring back to the example of FIG. 3, the detection signal 36 indicating an electrical overcurrent event in the current rail 16 may be provided to the circuit breaker 40. In response to receiving the detection signal 36 indicating an electrical overcurrent event, the circuit breaker 40 may interrupt and switch off the electrical current through the current rail 16.

In a further example, the method may include the further acts of detecting a short circuit event based on the second sense signal and interrupting the electrical current in response to detecting the short circuit event. Referring back to the example of FIG. 2, the second sense signal 12 may correspond to a voltage proportional to a temporal change of the electrical current through the current rail 16. In case of an occurring short circuit event, a temporal change of the electrical current and thus the value of the induced voltage may increase within a short time. Accordingly, the second sense signal 12 may be configured to indicate an occurrence of the short circuit event. Referring back to the example of FIG. 3, the circuit breaker 40 may also be configured to interrupt the electrical current through the electrical conductor 16 in response to the second sense signal 12 indicating the short circuit event. For example, the circuit breaker 40 may interrupt the electrical current if the second sense signal 12 exceeds a corresponding predetermined threshold value.

FIG. 5 illustrates a timing diagram for detecting an electrical overcurrent event in an electrical system. A detection of an electrical overcurrent event according to the timing diagram of FIG. 5 may be performed using a conventional device. In the illustrated diagram an absolute current value I of an electrical current through an electrical conductor (e.g., a bus) of the electrical system is plotted against time t. Specific values given in the following are example and in no way limiting.

During a regular operation of the electrical system the electrical current may have a nominal current value Iₙₒₘ until a short circuit event may occur. In one example, the nominal current level Iₙₒₘ may have a value of about 20 A. Due to the occurring short circuit event the value of the electrical current may increase. In the non-limiting illustrated example, the temporal change dl(t)/dt of the electrical current may be linear. In further examples, the slope of the electrical current may have a non-linear form. The slope of the electrical current may depend on the system inductance. In one example, a DC bus voltage V may have a value of about 800 V and a total inductance L in the short circuit condition may have a value of about 1 μH. Accordingly, the slope of the electrical current

$$\frac{dI ( t )}{dt} = \frac{V}{L}$$

may have a value of about 800 V/μH or about 800 A/μs.

After a certain amount of time the electrical current may reach a predetermined overcurrent threshold value Iₜₕ for the absolute current value. In one example, the threshold value Iₜₕ may be chosen to be greater than about twice the nominal current value Iₙₒₘ. In a specific case, the threshold value may have an example value of about 50 A. With the above specified current slope in the short circuit condition of about 800 A/μs, the threshold value Iₜₕ may be reached within a time of about 62 ns.

A further time interval may pass until the overcurrent event (or fault) is detected and yet another time interval may pass until the electrical current is finally shut off, for example using a circuit breaker as exemplarily described in connection with FIG. 3. Assuming a delay of the detection mechanism of about 1 μs (e.g., using a Hall-based current sensor or similar, not taking into account further delays), the electrical current may rise up to more than about 800 A (e.g., a factor of more than about 15 of the nominal threshold value) within this delay until finally shutting off. Such immense current values may easily result in damage or even destruction of the device and other components of the electrical system. Note that not only the detection mechanism of the sensor may add delay, e.g., the delay until finally switching off may even be larger.

FIG. 6 illustrates a timing diagram for detecting an electrical overcurrent event in an electrical system using a device in accordance with the disclosure. The considered short circuit scenario may be similar to the one previously discussed in connection with FIG. 5. In FIG. 6, a first bold line illustrates the absolute current value I of an electrical current through an electrical conductor (e.g., a bus) plotted against time t. In addition, a second bold line illustrates a voltage U induced across a first inductor plotted against time t. For the purpose of comparison, a thin dotted line illustrates the previously discussed graph of FIG. 5.

Similar to FIG. 5, during a regular operation of the electrical system, the electrical current may have a nominal current value Iₙₒₘ until a short circuit event may occur. Due to the short circuit event the value of the electrical current I may increase over time and a voltage V_{ind} may be induced across the first inductor. Note that the induced voltage V_{ind} is immediately available when the electrical current starts to rise, e.g., no delay is to be considered in this regard. Accordingly, if the value of the induced voltage V_{ind} is greater than a threshold value Vth for the induced voltage, the short circuit event (or fault) may be detected almost immediately.

After detecting the short circuit event, a further time interval may pass until the electrical current is interrupted and shut off, for example using a circuit breaker as exemplarily described in connection with the example of FIG. 3. Until shutting off the electrical current, the induced voltage V_{ind} may remain at a substantially constant level. When the electrical current is shut off and thus decreases over time, the voltage induced across the first inductor may become negative.

In the previously discussed example of FIG. 5, the threshold value for the absolute current value was Iₜₕ. In contrast to this, in the example of FIG. 6, the threshold value for the absolute current value may have been adjusted (lowered) based on the temporal change of the current as described in connection with previous examples. A comparison between the timing diagrams of FIGS. 5 and 6 shows that interrupting the electrical current may be performed faster, if the electrical overcurrent event is detected using a device in accordance with the disclosure.

### ASPECTS

In the following, devices and methods for detecting an electrical overcurrent event are explained using aspects.

Aspect 1 is a device for detecting an electrical overcurrent event, the device comprising: a current sensor configured to generate a first sense signal representative of an absolute current value of an electrical current through an electrical conductor; a sense unit configured to generate a second sense signal representative of a temporal change of the electrical current; an adjustment unit configured to adjust a previously set first threshold value for the absolute current value based on the second sense signal to provide an adjusted first threshold value; and a detection unit configured to detect an overcurrent event in the electrical conductor based on a comparison between the first sense signal and the adjusted first threshold value.

Aspect 2 is a device according to Aspect 1, wherein the sense unit comprises: a first inductor, wherein a voltage induced across the first inductor is based on the temporal change of the electrical current.

Aspect 3 is a device according to Aspect 2, wherein the sense unit comprises: a comparator configured to compare the induced voltage with a set second threshold value for the induced voltage and to output the second sense signal based on a comparison of the induced voltage and the set second threshold value.

Aspect 4 is a device according to Aspect 2 or 3, wherein an inductance value of the first inductor is known and well-defined.

Aspect 5 is a device according to one of Aspects 2 to 4, further comprising: a second inductor connected in a path of the electrical current, wherein the first inductor is coupled to the second inductor.

Aspect 6 is a device according to one of the preceding Aspects, wherein the adjustment unit comprises: a transistor configured to lower the first threshold value for the absolute current value, wherein an input of a control terminal of the transistor is based on the second sense signal.

Aspect 7 is a device according to one of the preceding Aspects, wherein the detection unit comprises: a comparator configured to compare the first sense signal with the adjusted first threshold value and to output a detection signal indicating an electrical overcurrent event based on a comparison of the first sense signal and the adjusted first threshold value.

Aspect 8 is a device according to Aspect 7, further comprising: a circuit breaker configured to receive the detection signal and to interrupt the electrical current in response to receiving the detection signal.

Aspect 9 is a device according to Aspect 8, wherein the circuit breaker is a solid-state circuit breaker.

Aspect 10 is a device according to Aspect 8 or 9, wherein: the second sense signal is configured to indicate a short circuit event, and the circuit breaker is configured to interrupt the electrical current in response to the second sense signal indicating the short circuit event.

Aspect 11 is a device according to one of Aspects 2 to 10, wherein the first inductor is a coil structure integrated into the current sensor.

Aspect 12 is a device according to one of Aspects 2 to 10, wherein the first inductor is a wire-on-chip structure configured for a calibration of the current sensor.

Aspect 13 is a device according to one of the preceding Aspects, wherein at least one of the sense unit, the adjustment unit or the detection unit is implemented as a discrete component external to the current sensor.

Aspect 14 is a device according to one of the preceding Aspects, wherein the electrical conductor is part of a DC system.

Aspect 15 is a method for detecting an electrical overcurrent event, the method comprising: generating a first sense signal representative of an absolute current value of an electrical current through an electrical conductor; generating a second sense signal representative of a temporal change of the electrical current; setting a first threshold value for the absolute current value; adjusting the first threshold value based on the second sense signal to provide an adjusted first threshold value; and detecting an electrical overcurrent event in the electrical conductor based on a comparison between the first sense signal and the adjusted first threshold value.

Aspect 16 is a method according to Aspect 15, further comprising: interrupting the electrical current in response to detecting the electrical overcurrent event.

Aspect 17 is a method according to Aspect 15 or 16, wherein generating the second sense signal comprises: measuring a voltage across an inductor, wherein the voltage is induced based on the temporal change of the electrical current.

Aspect 18 is a method according to Aspect 17, wherein generating the second sense signal comprises: setting a second threshold value for the induced voltage, and generating a voltage proportional to the temporal change of the electrical current based on a comparison between the induced voltage and the second threshold value.

Aspect 19 is a method according to Aspect 18, wherein adjusting the first threshold value comprises: lowering the first threshold value based on the voltage proportional to the temporal change of the electrical current.

Aspect 20 is a method according to one of Aspects 15 to 19, further comprising: detecting a short circuit event based on the second sense signal; and interrupting the electrical current in response to detecting the short circuit event.

While the present disclosure has been described with reference to illustrative aspects, this description is not intended to be construed in a limiting sense. Various modifications and combinations of the illustrative aspects, as well as other aspects of the disclosure, will be apparent to persons skilled in the art upon reference of the description. It is therefore intended that the appended claims encompass any such modifications or aspects.

1. A device for detecting an electrical overcurrent event, the device comprising:
a current sensor configured to generate a first sense signal representative of an absolute current value of an electrical current through an electrical conductor;
a sense unit configured to generate a second sense signal representative of a temporal change of the electrical current;
an adjustment unit configured to adjust a previously set first threshold value for the absolute current value based on the second sense signal to provide an adjusted first threshold value; and
a detection unit configured to detect an overcurrent event in the electrical conductor based on a comparison between the first sense signal and the adjusted first threshold value.

2. The device of claim 1, wherein the sense unit comprises:
a first inductor, wherein a voltage induced across the first inductor is based on the temporal change of the electrical current.

3. The device of claim 2, wherein the sense unit comprises:
a comparator configured to compare the induced voltage with a set second threshold value for the induced voltage and to output the second sense signal based on a comparison of the induced voltage and the set second threshold value.

4. The device of claim 2, wherein an inductance value of the first inductor is known and well-defined.

5. The device of claim 2, further comprising:
a second inductor connected in a path of the electrical current, wherein the first inductor is coupled to the second inductor.

6. The device of claim 1, wherein the adjustment unit comprises:
a transistor configured to lower the first threshold value for the absolute current value, wherein an input of a control terminal of the transistor is based on the second sense signal.

7. The device of claim 1, wherein the detection unit comprises:
a comparator configured to compare the first sense signal with the adjusted first threshold value, and to output a detection signal indicating an electrical overcurrent event based on a comparison of the first sense signal and the adjusted first threshold value.

8. The device of claim 7, further comprising:
a circuit breaker configured to receive the detection signal and to interrupt the electrical current in response to receiving the detection signal.

9. The device of claim 8, wherein the circuit breaker is a solid-state circuit breaker.

10. The device of claim 8, wherein:
the second sense signal is configured to indicate a short circuit event, and
the circuit breaker is configured to interrupt the electrical current in response to the second sense signal indicating the short circuit event.

11. The device of claim 2, wherein the first inductor is a coil structure integrated into the current sensor.

12. The device of claim 2, wherein the first inductor is a wire-on-chip structure configured for a calibration of the current sensor.

13. The device of claim 1, wherein at least one of the sense unit, the adjustment unit, or the detection unit is implemented as a discrete component external to the current sensor.

14. The device of claim 1, wherein the electrical conductor is part of a direct current (DC) system.

15. A method for detecting an electrical overcurrent event, the method comprising:
generating a first sense signal representative of an absolute current value of an electrical current through an electrical conductor;
generating a second sense signal representative of a temporal change of the electrical current;
setting a first threshold value for the absolute current value;
adjusting the first threshold value based on the second sense signal to provide an adjusted first threshold value; and
detecting an electrical overcurrent event in the electrical conductor based on a comparison between the first sense signal and the adjusted first threshold value.

16. The method of claim 15, further comprising:
interrupting the electrical current in response to detecting the electrical overcurrent event.

17. The method of claim 15, wherein generating the second sense signal comprises:
measuring a voltage across an inductor, wherein the voltage is induced based on the temporal change of the electrical current.

18. The method of claim 17, wherein generating the second sense signal comprises:
setting a second threshold value for the induced voltage, and
generating a voltage proportional to the temporal change of the electrical current based on a comparison between the induced voltage and the second threshold value.

19. The method of claim 18, wherein adjusting the first threshold value comprises:
lowering the first threshold value based on the voltage proportional to the temporal change of the electrical current.

20. The method of claim 15, further comprising:
detecting a short circuit event based on the second sense signal; and
interrupting the electrical current in response to detecting the short circuit event.
